(19) United States
(12) Patent Application Publication
(10) Pub. No.: US 2025/0329628 A1
(43) Pub. Date: Oct. 23, 2025

(54) SEMICONDUCTOR DEVICE

(71) Applicant: FUJI ELECTRIC CO., LTD., Kawasaki-shi (JP)

(72) Inventor: Mitsuhiro KAKEFU, Matsumoto-city (JP)

(73) Assignee: FUJI ELECTRIC CO., LTD., Kawasaki-shi (JP)

(21) Appl. No.: 19/252,712

(22) Filed: Jun. 27, 2025

Related U.S. Application Data
(63) Continuation of application No. PCT/JP2024/020469, filed on Jun. 5, 2024.

(30) Foreign Application Priority Data
Jul. 10, 2023 (JP) 2023-112777

(51) Int. Cl. H01L 23/498; H01L 23/00; H01L 23/373; H01L 23/60; H01L 25/16

(52) U.S. Cl. CPC H01L 23/49844; H01L 23/3735; H01L 23/3736; H01L 23/60; H01L 25/165; H01L 24/32; H01L 24/48; H01L 24/73; H01L 2224/32227; H01L 2224/32238; H01L 2224/48139; H01L 2224/48229; H01L 2224/73265

(57) ABSTRACT

A semiconductor device, including: an output conductive pattern having: a first part, having first and second sides extending in a first direction, and third and fourth sides extending a in second direction perpendicular to the first direction, and a second part, having first and second sides extending in the first direction, and a third side extending in the second direction, the third side of the second part being joined to third side of the first part; a first semiconductor chip disposed in the first part and including a control electrode provided on a front surface thereof; an output terminal disposed in the second part; and a control conductive pattern including a connection part electrically connected to the control electrode. The second part has a recess on the first side thereof and is recessed from the first side. The connection part is provided in the recess.

### CROSS-REFERENCE TO RELATED APPLICATION

This application is a continuation application of International Application PCT/JP2024/020469 filed on Jun. 5, 2024, which designated the U.S., which claims priority to Japanese Patent Application No. 2023-112777, filed on Jul. 10, 2023, the entire contents of which are incorporated herein by reference.

### BACKGROUND OF THE INVENTION

### 1. Field of the Invention

The embodiments discussed herein relate to a semiconductor device.

### 2. Background of the Related Art

A semiconductor device has a substrate including a circuit pattern on which semiconductor chips are disposed (see, for example, International Publication Pamphlet WO 2022/137811). In a NO. semiconductor device, such components are encapsulated in an encapsulating member (see, for example, Japanese Laid-open Patent Publication No. 2021-180234 and Japanese Laid-open Patent Publication No. 2022-046369). A semiconductor device may further include a heat dissipation plate, on which a plurality of semiconductor chip-mounted substrates are disposed, and wiring members that are electrically joined to the conductive patterns of the substrates, with these components being housed for inside a case (see, example, International Publication Pamphlet No. WO 2022/130951).

### SUMMARY OF THE INVENTION

According to an aspect of the present disclosure, there is provided a semiconductor device, including: an output conductive pattern, including: a first part, which is of a shape of a rectangle having first, second, third, and fourth sides, the first and second sides extending in a first direction, and the third and fourth sides extending in a second direction perpendicular to the first direction, and a second part, having a first side and a second side extending in the first direction, and a third side extending in the second direction, the third side of the second part being joined to the third side of the first part; a first semiconductor chip disposed in the first part of the output conductive pattern, the first semiconductor chip including a control electrode provided on a front surface thereof and at the third side of the first part; an output terminal disposed in the second part of the output conductive pattern; and a control conductive pattern including a connection part that is electrically connected to the control electrode, the control conductive pattern being adjacent to the second part of the output conductive pattern on an opposite side of the output conductive pattern to the first part in a plan view of the semiconductor device, wherein the second part of the output conductive pattern has a recess on the first side that is adjacent to the first part and is recessed from the first side toward the second side thereof, and the connection part of the control conductive pattern is provided in the recess.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a plan view of a semiconductor device;

FIG. 2 is a side view of the semiconductor device;

FIG. 3 is a plan view of the semiconductor device according to a first embodiment (in a state where a case has been removed);

FIG. 4 is a plan view of a semiconductor unit included in the semiconductor device according to the first embodiment;

FIG. 5 is a plan view of an insulated circuit board included in the semiconductor device according to the first embodiment;

FIG. 6 is a cross-sectional view of the insulated circuit board included in the semiconductor device according to the first embodiment;

FIG. 7 is a plan view of a semiconductor unit included in a semiconductor device according to a comparative example;

FIG. 8 is a plan view of a semiconductor device according to a second embodiment (in a state where a case has been removed);

FIG. 9 is a plan view of a semiconductor unit included in the semiconductor device according to the second embodiment;

FIG. 10 is a plan view of an insulated circuit board included in the semiconductor device according to the second embodiment;

FIG. 11 is a graph depicting terminal-to-wire distances that suppress discharging at different voltages;

FIG. 12 is a plan view of a semiconductor unit included in a semiconductor device according to a third embodiment; and

FIG. 13 is a plan view of a semiconductor unit included in a semiconductor device according to a fourth embodiment.

### DETAILED DESCRIPTION OF THE INVENTION

Preferred embodiments will be described below with reference to the accompanying drawings. In the following description, the expressions “front surface” and “upper surface” refer to an X-Y plane that faces upward (in the “+Z direction”) for a semiconductor device 1 in the drawings. In the same way, “upper” refers to an upward direction (or “+Z direction”) for the semiconductor device 1 in the drawings. The expressions “rear surface” and “lower surface” refer to an X-Y plane that faces downward (that is, in the “−Z direction”) for the semiconductor device 1 depicted in the drawings. In the same way, “down” refers to the downward direction (or “−Z direction”) for the semiconductor device 1 in the drawings. These expressions are used as needed to refer to the same directions in other drawings. The expression “high position” refers to an upper (that is “+Z side”) position on the semiconductor device 1 in the drawings. In the same way, the expression “low position” refers to a lower (that is “−Z side”) position on the semiconductor device 1 in the drawings. The expressions “front surface”, “upper surface”, “up”, “rear surface”, “lower surface”, “down” and “side surface” are merely convenient expressions used to specify relative positional relationships, and do not limit the technical scope of the present embodiments. For example, “up” and “down” do not necessarily refer to directions that are perpendicular to the ground. That is, the “up” and “down” directions are not limited to the direction of gravity. Additionally, in the following description, the expression “main component” refers to a component that composes 80% or higher by volume. The expression “substantially equal” may refer to a range of ±10%. The expressions “perpendicular”, “orthogonal”, and “parallel” may also refer to directions within a range of ±10°.

### First Embodiment

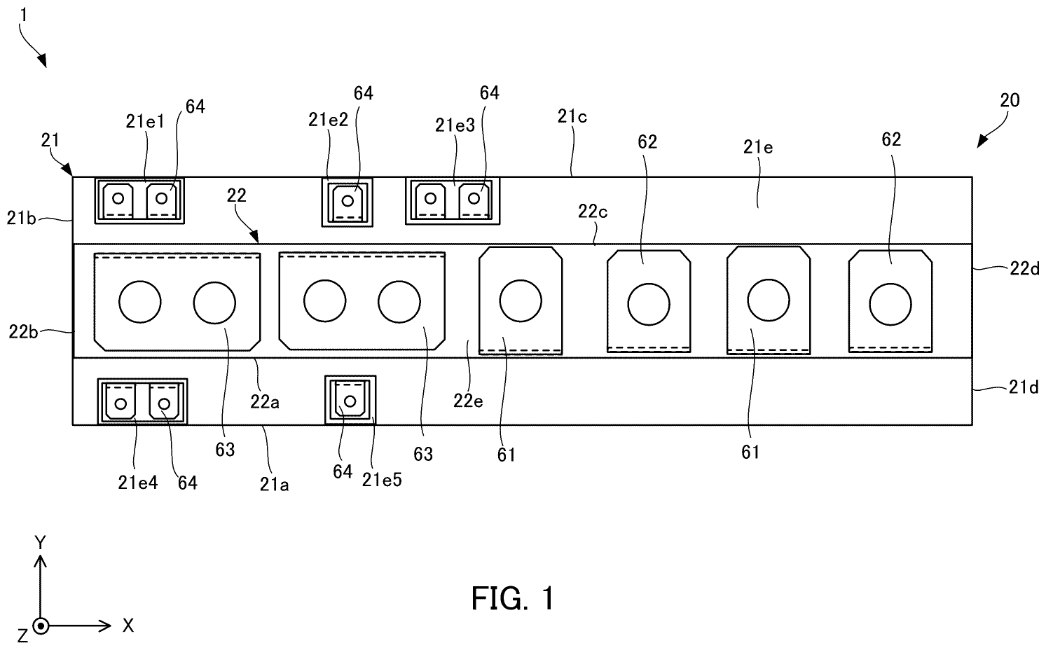

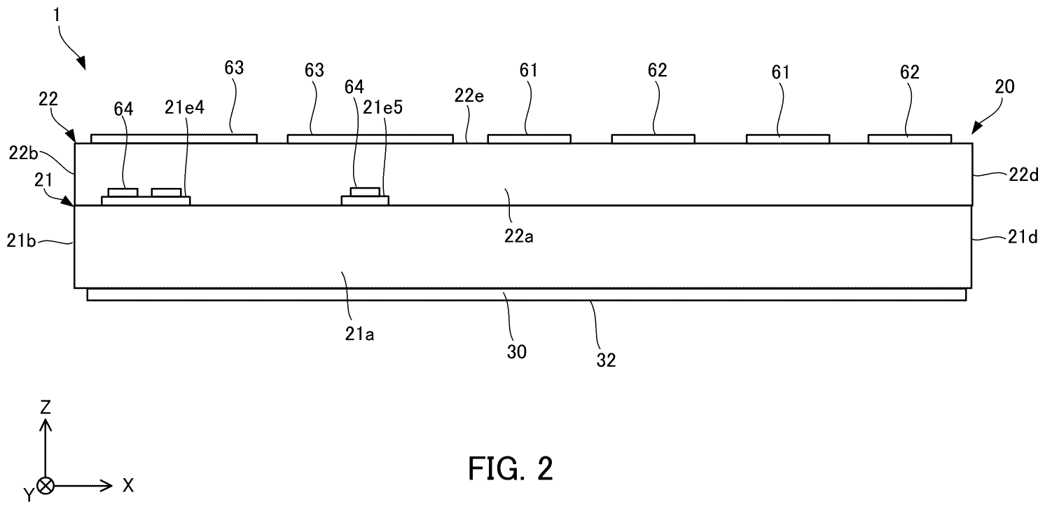

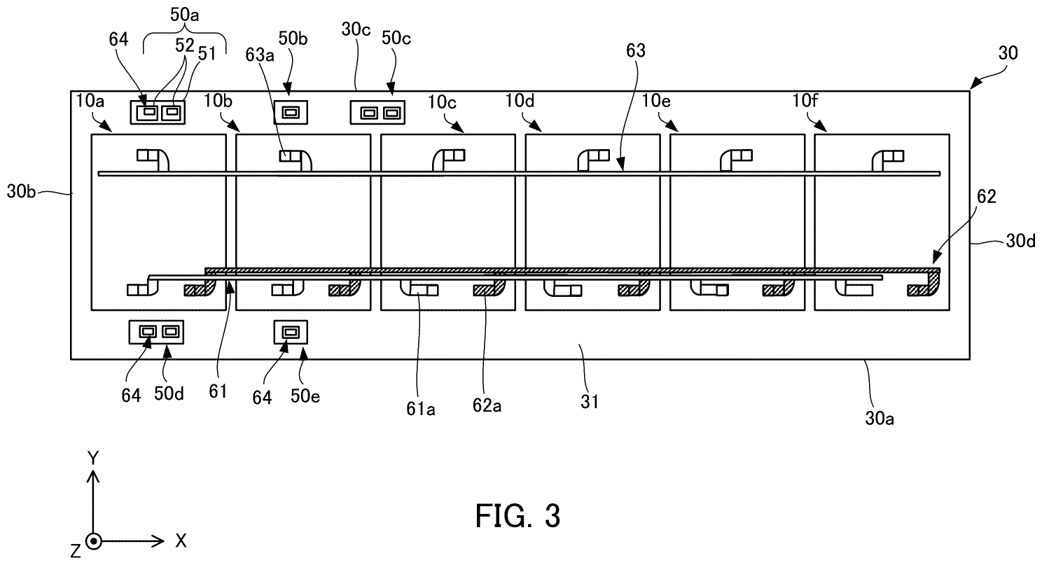

A semiconductor device will now be described with reference to FIGS. 1 to 3. FIG. 1 is a plan view of a semiconductor device. FIG. 2 is a side view of the semiconductor device. FIG. 3 is a plan view of a semiconductor device according to a first embodiment (in a state where a case has been removed). FIG. 2 is a side view of the semiconductor device 1 in FIG. 1 when viewed in the +Y direction. FIG. 3 is a plan view of the semiconductor device 1 in FIG. 1 with a case 20 removed. Note that for the semiconductor device 1 in FIG. 3, the semiconductor units included in the semiconductor device 1 have not been illustrated.

The semiconductor device 1 includes the case 20. The case 20 is attached to a heat dissipation base plate 30, described later, to which semiconductor units 10a to 10f are bonded. When attached to the heat dissipation base plate 30, the case 20 houses the semiconductor units 10a to 10f. The case 20 includes a lower housing portion 21 and an upper housing portion 22.

The lower housing portion 21 is shaped as a rectangular parallelepiped. In plan view, the lower housing portion 21 is surrounded on four sides by a long side wall 21a, a short side wall 21b, a long side wall 21c, and a short side wall 21d. The lower housing portion 21 also includes a lower front surface 21e in the opening surrounded by the long side wall 21a, the short side wall 21b, the long side wall 21c, and the short side wall 21d.

The lower front surface 21e includes control terminal regions 21e1 to 21e5. The control terminal region 21e1 is provided on a long side wall 21c-side edge portion of the lower front surface 21e at a position close to the short side wall 21b. The control terminal region 21e2 is provided on the long side wall 21c-side edge portion of the lower front surface 21e at a position next to the control terminal region 21e1 in the +X direction. The control terminal region 21e3 is provided on the long side wall 21c-side edge portion of the lower front surface 21e at a position next to the control terminal region 21e2 in the +X direction. The control terminal region 21e4 is provided on a long side wall 21a-side edge portion of the lower front surface 21e at a position close to the short side wall 21b so as to be opposite the control terminal region 21e1. The control terminal region 21e5 is provided on the long side wall 21a-side edge portion of the lower front surface 21e at a position next to the control terminal region 21e4 in the +X direction. The control terminal region 21e5 is also opposite the control terminal region 21e2.

Wiring members 64 used for control purposes are exposed in the control terminal regions 21e1 to 21e5. Connector parts at the ends of the wiring members 64 are exposed in the control terminal regions 21e1 to 21e5 and are bent over. The control terminal regions 21e1 to 21e5 may house nuts that face the bent connector parts of the wiring members 64.

The upper housing portion 22 is provided on the lower front surface 21e of the lower housing portion 21. The upper housing portion 22 is also shaped as a rectangular parallelepiped. In plan view, the upper housing portion 22 is surrounded on four sides by a long side wall 22a, a short side wall 22b, a long side wall 22c, and a short side wall 22d. The upper housing portion 22 also includes an upper front surface 22e in an opening surrounded by the long side wall 22a, the short side wall 22b, the long side wall 22c, and the short side wall 22d. The long side walls 22a and 22c may have the same length as the long side walls 21a and 21c of the lower housing portion 21.

The upper housing portion 22 is integrally provided in the center in the +Y direction of the lower front surface 21e of the lower housing portion 21. An opening is formed in a range of the lower front surface 21e of the lower housing portion 21 where the upper housing portion 22 is formed. The long side walls 22a and 22c are integrally connected to the lower front surface 21e of the lower housing portion 21. The short side walls 22b and 22d are integrally connected to the short side walls 21b and 21d of the lower housing portion 21 and are flush with the short side walls 21b and 21d, respectively.

On the upper front surface 22e, (connector parts of) wiring members 63, 63, 61, 62, 61, and 62 for an output, an output, a positive electrode, a negative electrode, a positive electrode, and a negative electrode, respectively, are provided in that order from the short side wall 22b toward the short side wall 22d (that is, along the +X direction). The wiring members 63, 63, 61, 62, 61, and 62 for an output, an output, a positive electrode, a negative electrode, a positive electrode, and a negative electrode are also bent over so as to face the upper front surface 22e. In this configuration, as depicted in FIG. 1, the output wiring member 63 is bent over in the −Y direction. The positive electrode wiring member 61, the negative electrode wiring member 62, the positive electrode wiring member 61, and the negative electrode wiring member 62 are bent over in the +Y direction. The upper front surface 22e may also house nuts facing the bent connector parts of the wiring members 63, 63, 61, 62, 61, and 62.

The case 20 with the configuration described above may be made of thermoplastic resin. Example resins include polyphenylene sulfide resin, polybutylene terephthalate resin, polybutylene succinate resin, polyamide resin, and acrylonitrile butadiene styrene resin.

As depicted in FIG. 3, the semiconductor device 1 includes the heat dissipation base plate 30, and the plurality of semiconductor units 10a to 10f, control wiring units 50a to 50e, and the wiring members 61, 62, and 63 for positive electrodes, negative electrodes, and outputs, which are provided on the heat dissipation base plate 30. Note that the semiconductor units 10a to 10f all have the same configuration. The semiconductor units 10a to 10f are collectively referred to as the “semiconductor units 10” when no distinction is made between them. Likewise, the control wiring units 50a to 50e are collectively referred to as the “control wiring units 50” when no distinction is made between them. The semiconductor units 10 will be described in detail later.

In the semiconductor device 1, the case 20 is attached onto the heat dissipation base plate 30. The case 20 covers the semiconductor units 10, the control wiring units 50, and the wiring members 61, 62, and 63 on the heat dissipation base plate 30.

The heat dissipation base plate 30 includes an upper surface 31 (see FIG. 3) and a lower surface 32 (see FIG. 2) which are both rectangular in plan view, and a long side 30a, a short side 30b, a long side 30c, and a short side 30d that surround the four sides of the upper surface 31. The heat dissipation base plate 30 is made of a metal with superior thermal conductivity. Example metals include aluminum, iron, silver, copper, magnesium, and an alloy containing at least one of these metals. The heat dissipation base plate 30 has copper as a main component. The surface of the heat dissipation base plate 30 may be plated to improve corrosion resistance. When doing so, examples of the plating material used include nickel, a nickel-phosphorus alloy, and a nickel-boron alloy.

A cooler (not depicted) may be attached via thermal grease to the lower surface 32 of the heat dissipation base plate 30 of the semiconductor device 1. By doing so, heat dissipation of the semiconductor device 1 is improved. Silicone mixed with a metal oxide filler may be given as an example of thermal grease. Examples of the cooler include a heat sink and a cooling device that uses water cooling. A plurality of fins may be formed on the heat sink. The plurality of fins may be directly formed on the lower surface 32 of the heat dissipation base plate 30. As examples, the heat sink may be made of aluminum, iron, silver, copper, or an alloy containing at least one of these metals, which have superior thermal conductivity.

The wiring members 61, 62, and 63 are positive electrode, negative electrode, and output wiring, respectively, and are connected to the semiconductor units 10a to 10f. The wiring members 61, 62, and 63 are parallel to the long sides 30a and 30c of the heat dissipation base plate 30 and extend from the semiconductor unit 10a toward the semiconductor unit 10f.

The wiring member 61 includes positive electrode terminals 61a joined respectively to the semiconductor units 10a to 10f. The wiring member 62 includes negative electrode terminals 62a joined respectively to the semiconductor units 10a to 10f. The wiring member 63 includes one output terminal 63a for each of the semiconductor units 10a to 10f. Such output terminals 63a are bonded to the semiconductor units 10a to 10f. Note that the wiring member 63 may include one or more output terminals 63a for of the each semiconductor units 10a to 10f. In the illustrated example, the wiring member 63 includes one output terminal 63a for each of the semiconductor units 10a to 10f. The wiring members 61, 62, and 63 and the semiconductor units 10a to 10f may be bonded by solder bonding or ultrasonic bonding, for example. When the case 20 is attached to the heat dissipation base plate 30, the connector parts of the wiring members 61, 62, and 63 extend from (that is, are inserted through) the upper front surface 22e of the upper housing portion 22 of the case 20 and are bent over.

The wiring members 61, 62, and 63 are made of metal with superior electrical conductivity. Example metals include silver, copper, nickel, and an alloy containing at least one of these metals. The surfaces of the wiring members 61, 62, and 63 may be plated to improve corrosion resistance. When doing so, examples of the plating material used include nickel, nickel-phosphorus alloy, and nickel-boron alloy. The output terminals 63a and 63b of the wiring members 63 will be described in detail later.

The control wiring units 50a, 50b, and 50c are disposed on the heat dissipation base plate 30 along the long side 30c on the +Y direction-side of the semiconductor units 10a, 10b, and 10c in FIG. 3. The control wiring units 50d and 50e are disposed on the heat dissipation base plate 30 along the long side 30a on the −Y direction-side of the semiconductor units 10a and 10b in FIG. 3.

Each control wiring unit 50 includes an insulating plate 51, a wiring board 52 provided on the insulating plate 51, and a wiring member 64 for control purposes that is bonded to the wiring board 52. In each control wiring units 50b and 50e out of the control wiring units 50, one pair of a wiring board 52 and a wiring member 64 for control purposes may be formed. In the other control wiring units 50, two pairs of a wiring board 52 and a wiring member 64 for control purposes may be formed.

Each insulating plate 51 is made of a ceramic with favorable thermal conductivity. As examples, such ceramic may be made of a composite material containing aluminum oxide and zirconium oxide that is added to aluminum oxide as a main component, or may be made of a material containing silicon nitride as a main component. Each insulating plate 51 is rectangular in shape in plan view. Corners of the insulating plate 51 may be chamfered into rounded or beveled shapes.

The wiring boards 52 are made of a metal with superior electrical conductivity. Example metals include silver, copper, nickel, and an alloy containing at least one of these metals. The surface of each wiring board 52 may be plated to improve corrosion resistance. When doing so, examples of the plating material used include nickel, nickel-phosphorus alloy, and nickel-boron alloy. The wiring boards 52 may be provided on the insulating plates 51 by forming a metal plate on the front surface of each insulating plate 51 and performing processing such as etching on the metal plate. Alternatively, the wiring boards 52 may be cut out from metal plates in advance and then pressure-bonded to the front surfaces of the insulating plates 51. The wiring boards 52 depicted in FIG. 3 are mere examples. The number, shape, size, and the like of the wiring boards 52 may be appropriately selected as needed.

The wiring members 64 for control purposes are made of metal a with superior electrical conductivity. Example metals include silver, copper, nickel, and an alloy containing at least one of these metals. The surface of each wiring member 64 may be plated to improve corrosion resistance. When doing so, examples of the used plating material include nickel, nickel-phosphorus alloy, and nickel-boron alloy. Each wiring member 64 is shaped as a strip, for example, and has a substantially uniform thickness along its entire length.

A lower end portion of each wiring member 64 is bonded to a wiring board 52. Such bonding is achieved by a bonding member. Alternatively, ultrasonic bonding may be used. As examples, the bonding member may be solder or sintered metal. Lead-free solder is used as the solder. As examples, the lead-free solder includes an alloy containing at least two of tin, silver, copper, zinc, antimony, indium, and bismuth as a main component. The solder may further contain an additive. Example additives include nickel, germanium, cobalt, and silicon. Solder containing an additive has improved wettability, gloss, and bonding strength, which improves reliability. Examples of the sintered material used in sintered metal include powdered silver, iron, copper, aluminum, titanium, nickel, tungsten, molybdenum, and an alloy containing any of these metals.

When the case 20 is attached to the heat dissipation base plate 30, the connector parts of the wiring members 64 are exposed from (that is, inserted through) the control terminal regions 21e1 to 21e5 of the upper housing portion 22 of the case 20, with the exposed parts then being bent over.

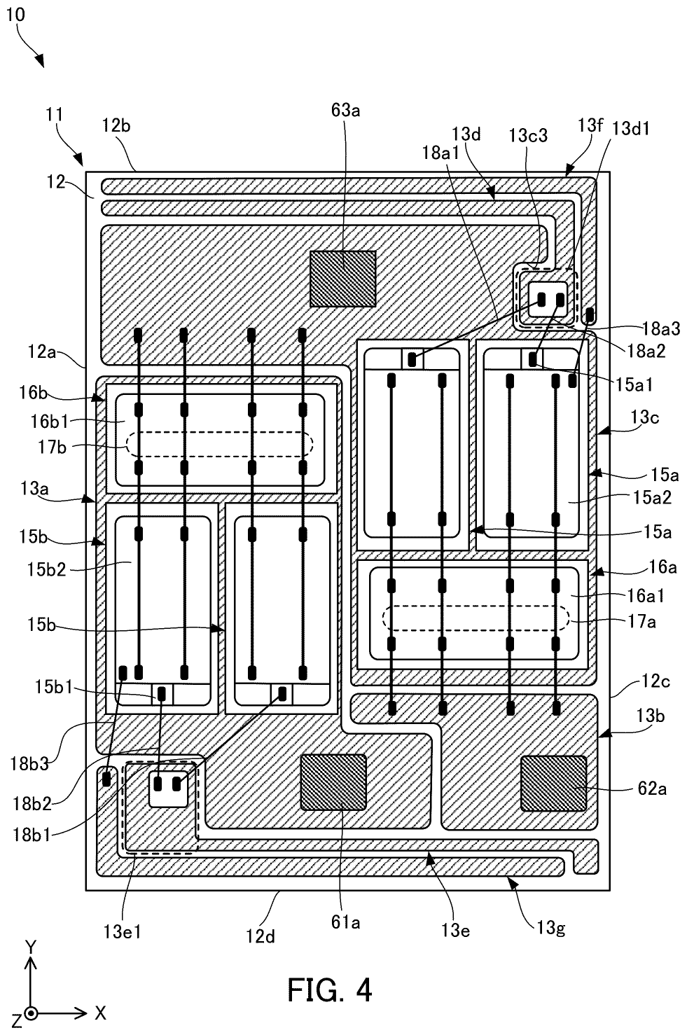

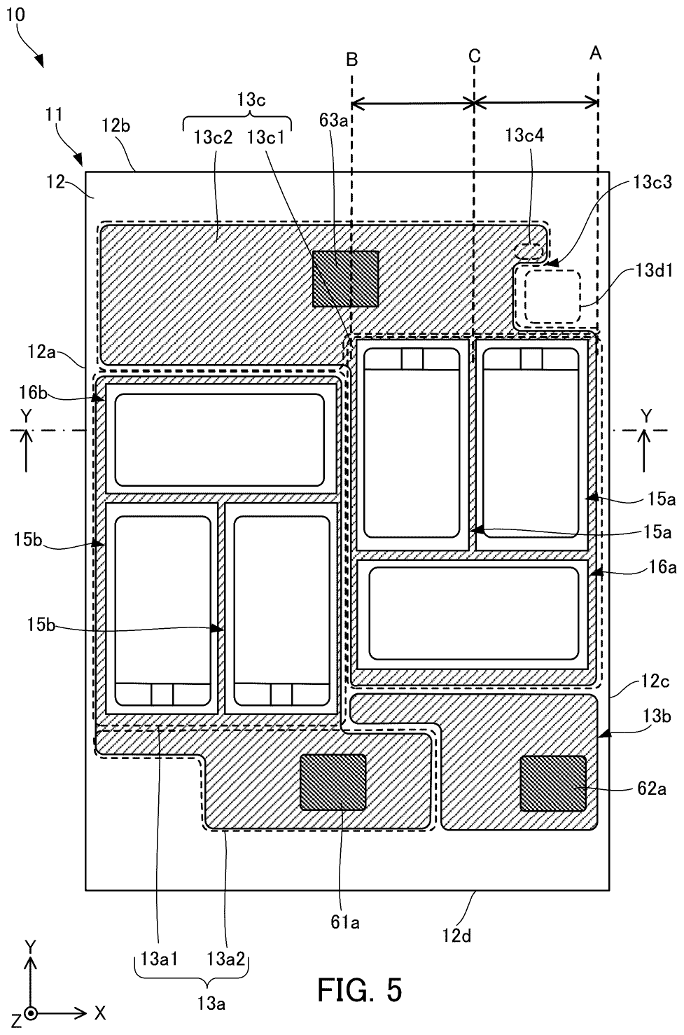

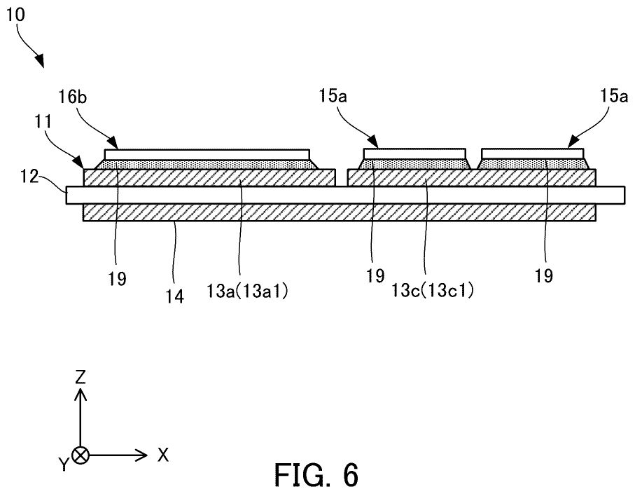

Next, the semiconductor units 10 included in the semiconductor device 1 will be described with reference to FIGS. 4 to 6. FIG. 4 is a plan view of a semiconductor unit included in the semiconductor device according to the first embodiment. FIG. 5 is a plan view of an insulated circuit board included in the semiconductor device according to the first embodiment, and FIG. 6 is a cross-sectional view of the insulated circuit board included in the semiconductor device according to the first embodiment. In FIG. 5, control conductive patterns 13d and 13e and sensing conductive patterns 13f and 13g are omitted from the insulated circuit board 11 included in the semiconductor unit 10 depicted in FIG. 4. In FIG. 5, a connection region 13d1 of the control conductive pattern 13d is indicated by a broken line. FIG. 6 is a cross-sectional view taken along a chain line Y-Y in FIG. 5.

The semiconductor units 10 are arranged on the heat dissipation base plate 30 in parallel with the long sides 30a and 30c, and adjacent semiconductor units 10 are electrically connected to each other by wires (not illustrated). Each semiconductor unit 10 includes at least an insulated circuit board 11, semiconductor chips 15a and 15b, and semiconductor chips 16a and 16b. As will be described later, each semiconductor unit 10 is wired using main current wires 17a and 17b and control wires 18a1, 18a2, 18b1, and 18b2.

The insulated circuit boards 11 are disposed on the upper surface 31 of the heat dissipation base plate 30 in a row along the long sides 30a and 30c of the heat dissipation base plate 30. Each insulated circuit board 11 may be bonded to the upper surface 31 of the heat dissipation base plate 30 via a bonding member (not illustrated). Example bonding members include a brazing material, in addition to the solder and the sintered metal described above. Example brazing materials contain at least one of aluminum alloy, titanium alloy, magnesium alloy, zirconium alloy, and silicon alloy as a main component. The insulated circuit boards 11 may be bonded by brazing using this type of bonding member.

Each insulated circuit board 11 includes an insulating plate 12, a plurality of conductive patterns formed on the front surface of the insulating plate 12, and a metal plate 14 formed on the rear surface of the insulating plate 12. The metal plate 14 may be seen in the cross-sectional view of the insulated circuit board 11 in FIG. 6. The insulating plate 12 and the metal plate 14 are rectangular in shape in plan view. Corners of the insulating plate 12 and the metal plate 14 may be chamfered into rounded or beveled shapes. The metal plate 14 is sized so as to be formed on the entire rear surface of the insulating plate 12 except for the outer peripheral portion of the insulating plate 12 in plan view.

The insulating plate 12 is rectangular in plan view, and is surrounded on four sides by a long side 12a, a short side 12b, a long side 12c, and a short side 12d in that order. Here, the long sides 12a and 12c are parallel to the ±Y direction, and the short sides 12b and 12d are parallel to the ±X direction. The insulating plate 12 is electrically insulating and has a material with superior thermal conductivity as a main component. Such material may be made of ceramic or an insulating resin. Example ceramics include aluminum oxide, aluminum nitride, and silicon nitride. Examples of the insulating resin include a paper phenol substrate, a paper epoxy substrate, a glass composite substrate, and a glass epoxy substrate.

The plurality of conductive patterns have a metal with superior electrical conductivity as a main component. Example metals include copper, aluminum, and an alloy containing at least one of these metals as a main component. The surfaces of the plurality of conductive patterns may also be plated to improve corrosion resistance. When doing so, examples of the used plating material include nickel, nickel-phosphorus alloy, and nickel-boron alloy. The number, shape, size, and the like of the plurality of conductive patterns may be appropriately selected as needed.

The plurality of conductive patterns include a positive electrode conductive pattern 13a, a negative electrode conductive pattern 13b, an output conductive pattern 13c, control conductive patterns 13d and 13e, and sensing conductive patterns 13f and 13g.

The positive electrode conductive pattern 13aincludes a chip region 13a1 and a terminal region 13a2 (see FIG. 5). The chip region 13a1 is rectangular in shape in plan view and is disposed on the long side 12a-side of the insulating plate 12 so as to be parallel to the long side 12a. The chip region 13a1 is closer to the short side 12d than the center in the ±Y direction of the insulating plate 12. The width in the ±X direction of the chip region 13a1 may be substantially half the width of the insulating plate 12 in that direction. On the −Y direction-side of the chip region 13a1, the two semiconductor chips 15b are bonded via bonding members 19 so as to be aligned in the +X direction with their control electrodes 15b1 facing the short side 12d. The semiconductor chip 16b is disposed via a bonding member 19 in the chip region 13a1 so as to be adjacent to the semiconductor chip 15b on the +Y direction side. As one example, the bonding members 19 may be the solder or sintered metal described above.

The terminal region 13a2 is connected to an −Y direction-end portion of the chip region 13a1 and extends from that end portion in the +X direction (that is, toward the long side 12c) in parallel with the short sides 12b and 12d. The +X direction-end portion of the terminal region 13a2 extends further in the +X direction than the +X direction-end portion of the chip region 13a1. A positive electrode terminal 61a of the wiring member 61 is bonded to the terminal region 13a2.

The negative electrode conductive pattern 13b is disposed adjacent in the +X direction to the −Y direction-side part of the positive electrode conductive pattern 13a that includes the terminal region 13a2 (see FIG. 5). The negative electrode conductive pattern 13b is adjacent to the positive electrode conductive pattern 13a and a chip region 13c1 of the output conductive pattern 13c. The negative electrode conductive pattern 13b is substantially rectangular in shape in plan view and includes a part that protrudes in the −X direction from the +Y direction (short side 12b)-side of the −X direction (long side 12a)-side end portion. This protruding part of the negative electrode conductive pattern 13b is disposed between the terminal region 13a2 of the positive electrode conductive pattern 13a and the chip region 13c1 of the output conductive pattern 13c. A negative electrode terminal 62a of the wiring member 62 is bonded to the negative electrode conductive pattern 13b. The negative electrode terminal 62a and the positive electrode terminal 61a are disposed in a line in parallel with the ±X direction.

The output conductive pattern 13c includes the chip region 13c1 and a terminal region 13c2 (see FIG. 5). The chip region 13c1 is substantially the same size as the chip region 13a1 of the positive electrode conductive pattern 13a. The chip region 13c1 has sides that extend in the +Y direction and the −X direction that is perpendicular the +Y direction, is rectangular in shape in plan view, and is disposed on the long side 12c-side of the insulating plate 12 so as to be parallel to the long side 12c. The chip region 13c1 is closer to the short side 12b than the center in the ±Y direction of the insulating plate 12. That is, the chip region 13c1 is located closer to the short side 12b than the chip region 13a1 of the positive electrode conductive pattern 13a. The width of the chip region 13c1 in the ±X direction may be substantially half the width of the insulating plate 12 in the same direction. On the +Y direction-side of the chip region 13c1, the two semiconductor chips 15a are bonded in parallel via bonding members 19 with their control electrodes 15a1 facing the short side 12b. That is, the two semiconductor chips 15a are disposed so that the control electrodes 15a1 face a first direction (the +Y direction) which is the opposite side (the short side 12b-side) to the negative electrode conductive pattern 13b. The semiconductor chips 15a are examples of “first semiconductor chips” for the present embodiment. The semiconductor chip 16a is bonded via a bonding member 19 to the chip region 13a1 so as to be adjacent to the two semiconductor chips 15a on the −Y direction side. The semiconductor chip 16a is one example of a “second semiconductor chip” for the present embodiment.

The terminal region 13c2 is connected to the +Y direction-end portion of the chip region 13c1. The terminal region 13c2 extends from the +X direction side (or “first side”) of such end portion toward the −X direction-side (or “second side”). The terminal region 13c2 is parallel to the short sides 12b and 12d and extends to the long side 12a. An output terminal 63a of the wiring member 63 is bonded to this terminal region 13c2. The output terminal 63a is disposed at the center of the width in the ±X direction of the terminal region 13c2.

The terminal region 13c2 includes a recess 13c3. In plan view, the recess 13c3 is a recess on the +X direction side (or “first side”) of the terminal region 13c2 of the output conductive pattern 13c, and is recessed from the +X direction side (first side) toward the-X direction side (second side). In plan view, the recess 13c3 is U-shaped with an opening on the +X direction side. The recess 13c3 may be located in the terminal region 13c2 between the center line C of the chip region 13c1 and an end portion A. It is preferable for the position of the recess 13c3 to be close to the end portion A and adjacent to the chip region 13c1.

The terminal region 13c2 includes a linking region 13c4. This linking region 13c4 connects the semiconductor unit 10 and another semiconductor unit 10 disposed adjacent to the semiconductor unit 10 on the +X direction side via wiring with wires. The linking region 13c4 is included in a +X direction-side (first side) end portion of the terminal region 13c2 along the recess 13c3.

The control conductive pattern 13d includes a connection region 13d1 at an end portion thereof. The connection region 13d1 is disposed in the recess 13c3 of the output conductive pattern 13c. The control conductive pattern 13d is substantially L-shaped in plan view, and extends from the connection region 13d1 along the outer edge of the terminal region 13c2 of the output conductive pattern 13c in parallel with the long side 12c and the short side 12b to the long side 12a.

The control conductive pattern 13e includes a connection region 13e1 at an end portion thereof. The connection region 13e1 is disposed adjacent to the terminal region 13a2 of the positive electrode conductive pattern 13a in the-X direction. The control conductive pattern 13e is substantially L-shaped in plan view, and extends from the connection region 13e1 along the outer edges of the terminal region 13a2 of the positive electrode conductive pattern 13a and the negative electrode conductive pattern 13b in parallel to the short side 12d to the long side 12c.

The sensing conductive pattern 13f is parallel to the long side 12c and the short side 12b along the control conductive pattern 13d, and extends to the long side 12a. A long side 12c-side end portion of the sensing conductive pattern 13f and an output electrode 15a2 of a semiconductor chip 15a are electrically connected by a sensing wire 18a3. The sensing conductive pattern 13g is parallel to the long side 12a and the short side 12d along the control conductive pattern 13e, and extends to the long side 12c. A long side 12a-side end portion of the sensing conductive pattern 13g and an output electrode 15b2 of a semiconductor chip 15b are electrically connected by a sensing wire 18b3.

The metal plate 14 has a smaller area than the insulating plate 12 and has a similar rectangular shape to the insulating plate 12. Corners of the metal plate 14 may be chamfered into curved or beveled shapes. The metal plate 14 is smaller in size than the insulating plate 12 and is formed on the entire surface of the insulating plate 12 except for edge portions. The metal plate 14 is made of a metal with superior thermal conductivity as a main component. Example metals include copper, aluminum, and an alloy containing at least one of these metals. In the semiconductor device 1 according to the present embodiment, the metal plate 14 has copper as a main component. To improve corrosion resistance, the metal plate 14 may be plated. When doing so, examples of the used plating material include nickel, nickel-phosphorus alloy, and nickel-boron alloy.

As examples, direct copper bonding (DCB) substrates, active metal brazed (AMB) substrates, or resin insulating substrates may be used as the insulated circuit boards 11 with the configuration described above.

As one example, the semiconductor chips 15a and 15b have silicon as a main component and include the same type of switching elements. As one example, the switching elements are insulated gate bipolar transistors (IGBT). The withstand voltage of the semiconductor chips 15a and 15b is 1200 V.

Each of the semiconductor chips 15a and 15b includes a collector electrode as an input electrode on the rear surface, and a gate electrode as a control electrode 15a1 or 15b1 and an emitter electrode as an output electrode 15a2 or 15b2 on the front surface. The control electrodes 15a1 and 15b1 may be provided at the center of one edge on the front surfaces of the semiconductor chips 15a and 15b. Alternatively, the control electrodes 15a1 and 15b1 are not necessarily provided at the center of one edge on the front surfaces of the semiconductor chips 15a and 15b, and may be displaced from the center in the ±X direction. The widths in the ±X direction of the semiconductor chips 15a and 15b may be equal to or less than half the width in the same direction of the chip region 13c1 of the output conductive pattern 13c, described later.

The semiconductor chips 16a and 16b have silicon as a main component, for example, and include diode elements of the same type. As one example, such diode elements are free wheeling diodes (FWD), such as Schottky barrier diodes (SBD) or P-intrinsic-N (PiN) diodes. The semiconductor chips 16a and 16b each include an output electrode (or “cathode electrode”) as a main electrode on the rear surface and an input electrode 16a1 or 16b1 (or “anode electrode”) as a main electrode on the front surface.

The two semiconductor chips 15a are aligned and bonded to the output conductive pattern 13c with the control electrodes 15a1 facing the short side 12b. The two semiconductor chips 15b are aligned and bonded to the positive electrode conductive pattern 13a with the control electrodes 15b1 facing the short side 12d. That is, the control electrodes 15a1 are provided on a +Y direction-side portion of the front surfaces of the semiconductor chips 15a. The control electrodes 15b1 are provided on −Y direction-side portions of the front surfaces of the semiconductor chips 15b. The semiconductor chip 16a is bonded to the output conductive pattern 13c so as to be adjacent to the semiconductor chips 15a in the −Y direction. The semiconductor chip 16b is bonded to the positive electrode conductive pattern 13a so as to be adjacent to the semiconductor chips 15b in the +Y direction. Examples of the bonding used here include the solder and sintered metal described above.

The output electrodes 15a2 of the semiconductor chips 15a, the input electrode 16a1 of the semiconductor chip 16a, and the negative electrode conductive pattern 13b are electrically connected by the main current wires 17a. The control electrodes 15a1 of the semiconductor chips 15a and the connection region 13d1 of the control conductive pattern 13d are electrically connected by the control wires 18a1 and 18a2. An end portion of the sensing conductive pattern 13f and the output electrode 15a2 of a semiconductor chip 15a are electrically connected by the sensing wire 18a3.

The output electrodes 15b2 of the semiconductor chips 15b, the input electrode 16b1 of the semiconductor chip 16b, and the output conductive pattern 13c are electrically connected by the main current wires 17b. The control electrodes 15b1 of the semiconductor chips 15b and the control conductive pattern 13e are electrically connected by the control wires 18b1 and 18b2. An end portion of the sensing conductive pattern 13g and the output electrode 15b2 of a semiconductor chip 15b are electrically connected by the sensing wire 18b3.

The main current wires 17a and 17b, the control wires 18a1, 18a2, 18b1, and 18b2, and the sensing wires 18a3 and 18b3 have a material with superior electrical conductivity as a main component. Example materials include gold, copper, aluminum, and an alloy containing at least one of these metals. The main current wires 17a and 17b and the control wires 18a1, 18a2, 18b1, and 18b2 are preferably aluminum alloy containing a trace amount of silicon. The main current wires 17a and 17b are larger in diameter than the control wires 18a1, 18a2, 18b1, and 18b2 and the sensing wires 18a3 and 18b3.

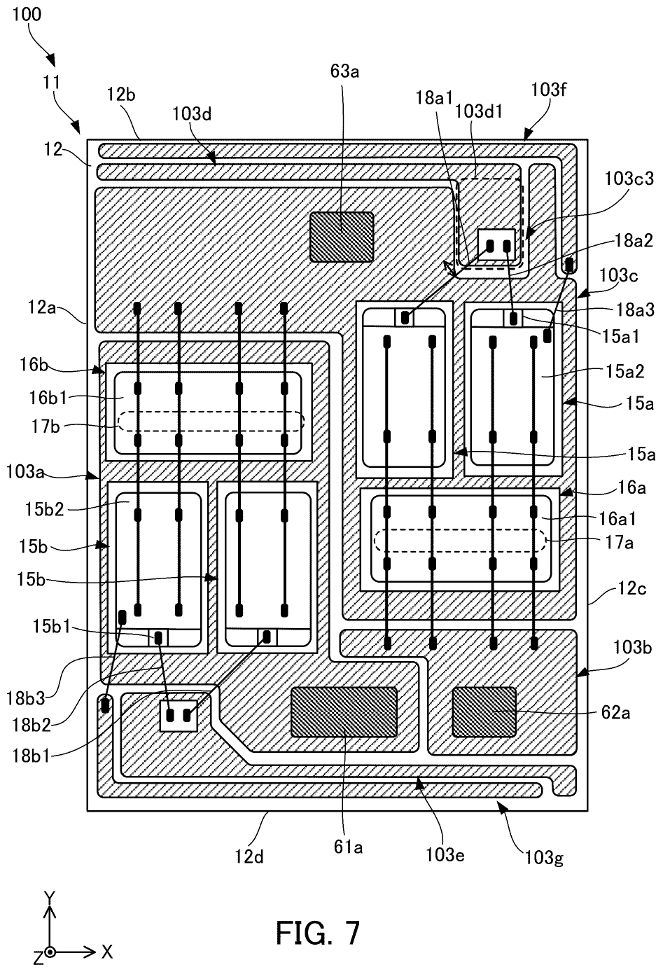

A semiconductor unit 100 that is a comparative example to be compared with the semiconductor units will now be described with reference to FIG. 7. FIG. 7 is a plan view of a semiconductor unit included in a semiconductor device according to this comparative example. The semiconductor device according to this comparative example uses the semiconductor units 100 in place of the semiconductor units 10 in the semiconductor device 1 according to the first embodiment. The semiconductor unit 100 differs from the semiconductor units 10 in only the shapes of the circuit patterns. The remaining configuration and wiring are the same as in the semiconductor units 10.

Each semiconductor unit 100 includes a plurality of conductive patterns. The plurality of conductive patterns include a positive electrode conductive pattern 103a, a negative electrode conductive pattern 103b, an output conductive pattern 103c, control conductive patterns and 103d 103e, and sensing conductive patterns 103f and 103g.

The positive electrode conductive pattern 103a is provided on the long side 12a-side of the insulating plate 12 so as to be separated from the short sides 12b and 12d, is parallel to the long side 12a and the short side 12d, and is substantially L-shaped. The positive electrode terminal 61a of the wiring member 61 is bonded to the positive electrode conductive pattern 103a. The positive electrode terminal 61a of the wiring member 61 is bonded to the short side 12d-side of the positive electrode conductive pattern 103a.

The negative electrode conductive pattern 103b is provided on the long side 12c-side of the insulating plate 12 so as to be separated from the short sides 12b and 12d. The negative electrode terminal 62a of the wiring member 62 is bonded to the negative electrode conductive pattern 103b. The negative electrode terminal 62a of the wiring member 62 is bonded to the short side 12d-side of the negative electrode conductive pattern 103b.

The output conductive pattern 103c is substantially L-shaped in plan view and includes parts that are parallel to the long side 12c and the short side 12b of the insulating plate 12. The output conductive pattern 103c is provided on the long side 12c-side of the insulating plate 12 and is separated from the short side 12d. The output conductive pattern 103c is provided with a recess on the long side 12c-side facing the short side 12b. In the same way as in the first embodiment, the output conductive pattern 103c is bonded to one output terminal 63a of the wiring member 63. The output terminal 63a of the wiring member 63 is bonded to a center portion of the width in the ±X direction of the output conductive pattern 103c.

The control conductive patterns 103d and 103e are each substantially L-shaped in plan view. The control conductive pattern 103d includes the connection region 103d1 disposed in the recess of the output conductive pattern 103c, is adjacent to the output conductive pattern 103c on the +Y direction side, and is provided parallel to the short side 12b. The control conductive pattern 103e is provided adjacent to the positive electrode conductive pattern 103a and the negative electrode conductive pattern 103b in the −Y direction and is parallel to the short side 12d.

The sensing conductive patterns 103f and 103g are substantially L-shaped in plan view. The sensing conductive pattern 103f is provided on the long side 12c side and the short side 12b side in parallel with the long side 12c and the short side 12b. The sensing conductive pattern 103g is provided on the long side 12a side and the short side 12d side in parallel with the long side 12a and the short side 12d.

In the semiconductor unit 100 described above, the wiring member 63 is bonded to the output conductive pattern 103c using one output terminal 63a. In recent years, the semiconductor chips 15a have used increasingly high voltages and currents. It is especially important for the output terminal 63a that outputs a high voltage to have sufficiently high withstand voltage characteristics with respect to the connection region 103d1 of the control conductive pattern 103d. To achieve such withstand voltage characteristics, sufficient distance is needed between the output terminal 63a and the connection region 103d1 of the control conductive pattern 103d.

For this reason, the semiconductor device 1 includes the semiconductor chips 15a, the output conductive pattern 13c, the output terminal 63a, and the control conductive pattern 13d. The semiconductor chips 15a each include a control electrode 15a1 provided on a first direction (+Y direction)-side edge of the front surface.

The output conductive pattern 13c includes a chip region 13c1 as a “first part” and a terminal region 13c2 as a “second part”. The semiconductor chips 15a are disposed in the chip region 13c1, which has sides extending in the first direction (the +Y direction) and the second direction (the −X direction) which is perpendicular to the first direction.

The terminal region 13c2 is connected to the first direction (+Y direction)-side of the chip region 13c1, and extends in the second direction (−X direction) from a first side (+X direction side) to a second side (−X direction side) in the first direction (+Y direction) of the chip region 13c1. The output terminal 63a is disposed in the terminal region 13c2 of the output conductive pattern 13c.

The control conductive pattern 13d includes a connection region 13d1 that is electrically connected to the control electrodes 15a1. The control conductive pattern 13d is adjacent to the opposite side of the terminal region 13c2 to the chip region 13c1 in plan view.

The terminal region 13c2 of the output conductive pattern 13c also has a recess 13c3 that is recessed from the first side toward the second side on the +X direction side of the terminal region 13c2 and adjacent to the chip region 13c1 in plan view. The connection region 13d1 of the control conductive pattern 13d is provided in this recess 13c3.

When compared to the configuration of the comparative example, the connection region 13d1 of the control conductive pattern 13d is further separated from the output terminal 63a, for example. This means that sufficient withstand voltage characteristics are achieved between the connection region 13d1 of the control conductive pattern 13d and the output terminal 63a. As a result, the occurrence of failures for the semiconductor chips 15a is suppressed, which suppresses a fall in the reliability of the semiconductor device 1.

### Second Embodiment

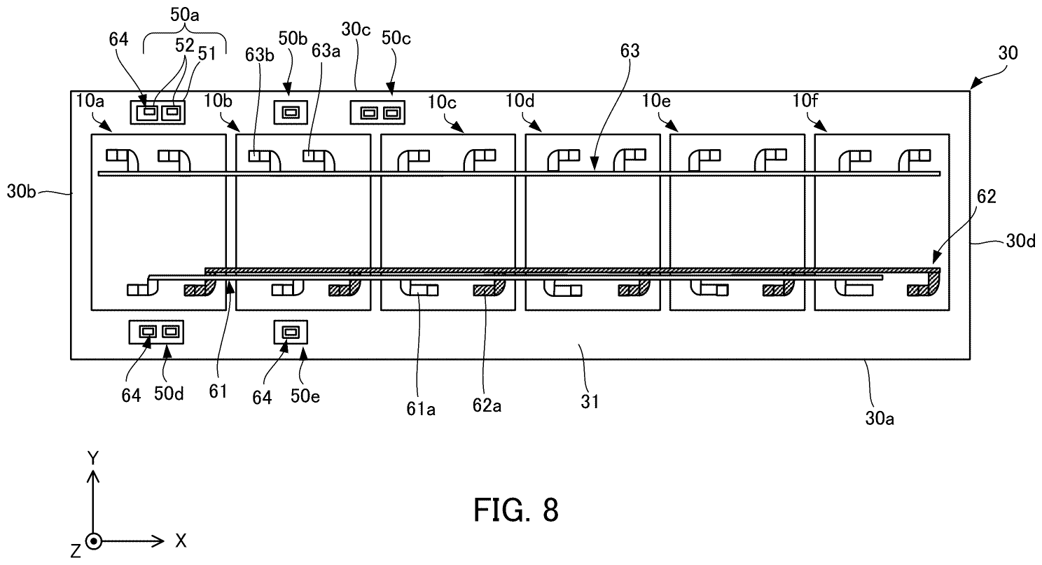

In this second embodiment, the wiring member 63 of the first embodiment includes at least two output terminals on each semiconductor unit 10. Although the present embodiment also includes configurations including three or more output terminals, for ease of explanation, a configuration with two output terminals will be described here. First, a semiconductor device of this configuration will be described with reference to FIG. 8. FIG. 8 is a plan view of the semiconductor device according to the second embodiment (in a state where the case has been removed).

The semiconductor device 1 according to the second embodiment is the same as depicted in FIGS. 1 and 2. However, the wiring member 63 included in the semiconductor device 1 according to the second embodiment includes two output terminals 63a and 63b corresponding to each of the semiconductor units 10a to 10f. The output terminals 63a and 63b are bonded to each of the semiconductor units 10a to 10f.

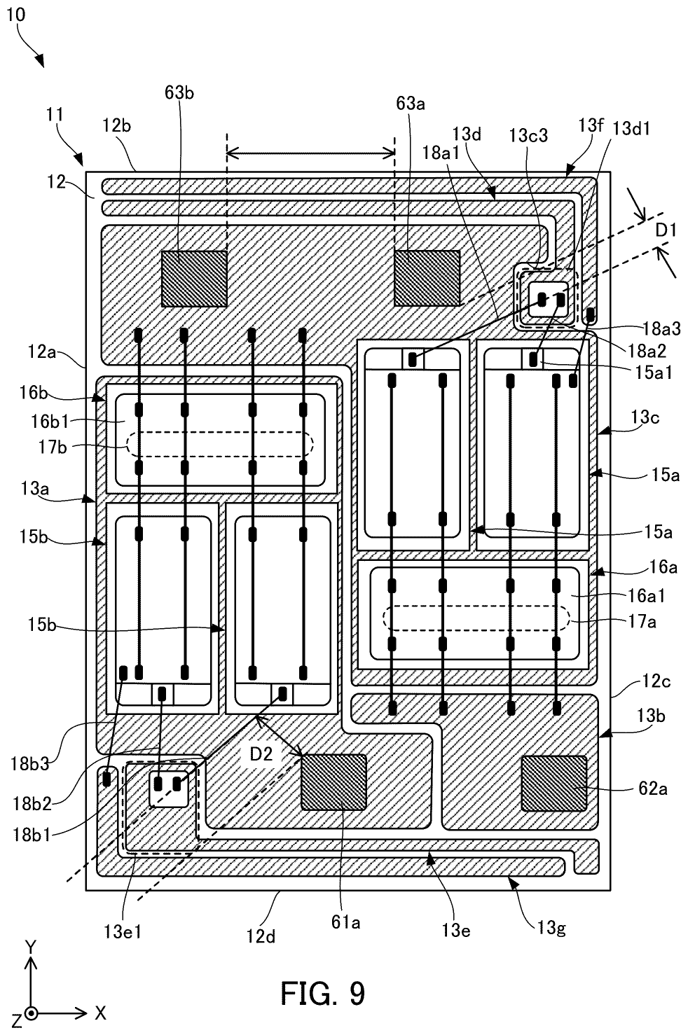

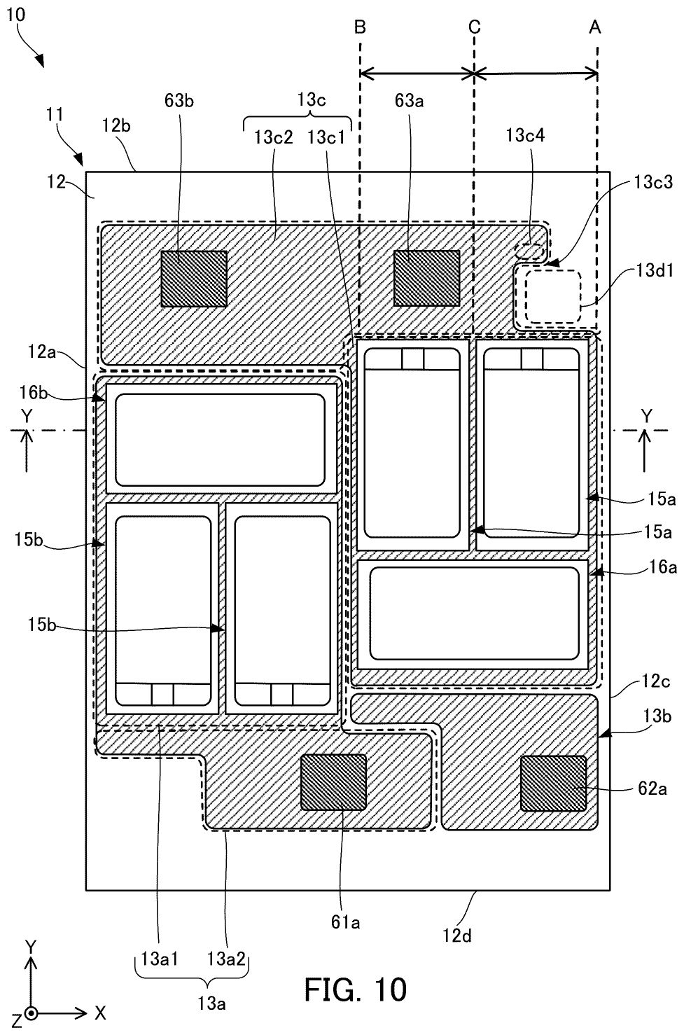

Next, the semiconductor units 10 included in the semiconductor device 1 according to the second embodiment will be described with reference to FIGS. 9 and 10. FIG. 9 is a plan view of a semiconductor unit included in the semiconductor device according to the second embodiment, and FIG. 10 is a plan view of an insulated circuit board included in the semiconductor device according to the second embodiment. In FIG. 10, the control conductive patterns 13d and 13e and the sensing conductive patterns 13f and 13g have been omitted from the insulated circuit board 11 included in the semiconductor unit 10 illustrated in FIG. 9. In FIG. 10, a connection region 13d1 of the control conductive pattern 13d is indicated by a broken line.

In each semiconductor unit 10 according to the second embodiment, as depicted in FIGS. 9 and 10, two output terminals 63a and 63b are disposed side by side in the ±X direction in the terminal region 13c2 of the output conductive pattern 13c included in the insulated circuit board 11 of the first embodiment.

As mentioned earlier, the voltage and current used by the semiconductor chips 15a have increased in recent years. Accordingly, compared to a configuration with a single output terminal 63a, by using the two output terminals 63a and 63b, it becomes easier for current to flow to the wiring member 63. When this configuration is used however, it is important to space the output terminals 63a and 63b apart by a certain distance or greater. When the interval between the output terminals 63a and 63b is narrow, thermal interference will occur due to the passing current generating heat at the output terminals 63a and 63b. Accordingly, by setting the interval between the output terminals 63a and 63b at a certain distance or greater, the temperatures of the output terminals 63a and 63b will fall, which lowers the temperature of the semiconductor unit 10. The output terminals are not limited to the two output terminals 63a and 63b, and three or more output terminals may be provided. In this case, the three output terminals are arranged side by side in the ±X direction in the terminal region 13c2 of the output conductive pattern 13c. With this configuration also, it is important to space the output terminals apart by a certain distance or greater.

Since it is important to space the output terminals 63a and 63b apart by a certain distance or more on the lower arm-side of a semiconductor unit 10, the shortest distance D1 between the output terminal 63a closest to the connection portion 13d1 out of the two output terminals 63a and 63b and the control wire 18a1 may become short. When this shortest distance D1 is reduced, partial discharge may occur when a voltage is applied to the output terminal 63a. When this happens, there is increased risk of the output terminal 63a and the control wire 18a1 being short-circuited, which will cause the semiconductor chips 15a to fail. Note that when there are three or more output terminals also, there is a concern that the shortest distance D1 between the output terminal closest to the connection portion 13d1 out of the three or more output terminals and the control wire 18a1 will become short.

According to this second embodiment however, the connection region 13d1 of the control conductive pattern 13d included in the insulated circuit board 11 is separated from the output terminal 63a toward the long side 12c. This means that the shortest distance D1 between the control wire 18a1 and the output terminal 63a may be increased. Accordingly, even when a voltage is applied to the output terminal 63a, partial discharge does not occur between the output terminal 63a and the control wire 18a1, which prevents short-circuiting between the output terminal 63a and the control wire 18a1. As a result, the occurrence of failures for the semiconductor chips 15a is suppressed.

Note that on the upper arm-side of the semiconductor unit 10, the position of the positive electrode terminal 61a of the wiring member 61 is changeable as appropriate because there is only one positive electrode terminal 61a. Accordingly, the shortest distance D2 between the control wire 18b1 and the positive electrode terminal 61a may be made sufficiently large, so that short circuits do not occur between the control wire 18b1 and the positive electrode terminal 61a.

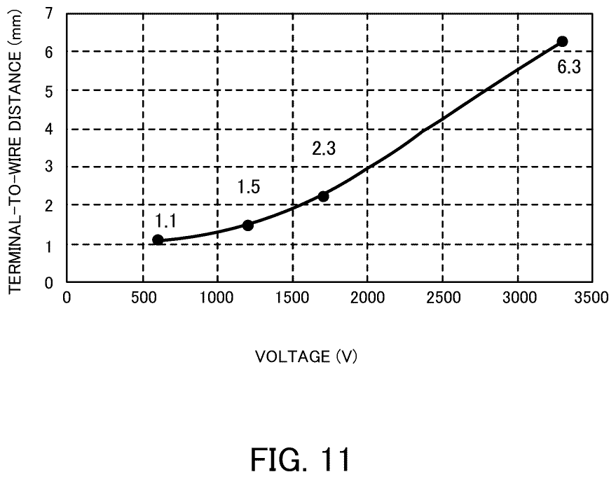

Next, the shortest distance D1 between the control wire 18a1 and the output terminal 63a will be described with reference to FIG. 11. FIG. 11 is a graph depicting terminal-to-wire distances that suppress discharging at different voltages. In FIG. 11, the horizontal axis represents the applied voltage [V], and the vertical axis represents the terminal-to-wire distance [mm] that suppresses discharging at different voltages.

According to the graph in FIG. 11, as the applied voltage increases, the distance between the terminal and the wire that suppresses discharging increases in keeping with the voltage. The withstand voltage of the semiconductor chips 15a is 1200 V. According to the graph in FIG. 11, the distance at this voltage is about 1.5 mm. In the configurations in FIGS. 9 and 10, the actual shortest distance D1 is around 2.5 mm. Since this is larger than 1.5 mm, the occurrence of partial discharging from the output terminal 63a to the control wire 18a1 is suppressed.

In this way, in the semiconductor device 1 according to the second embodiment, the connection region 13d1 of the control conductive pattern 13d is separated from the output terminal 63a. This means that sufficient withstand voltage characteristics may be achieved between the connection region 13d1 of the control conductive pattern 13d and the output terminal 63a. The output terminal 63a and the output terminal 63b may also be spaced apart. As a result, it is possible, while improving the ease with which current flows from the output terminals 63a and 63b to the wiring member 63, to suppress the occurrence of failures at the semiconductor chips 15a, which suppresses a fall in the reliability of the semiconductor device 1.

### Third Embodiment

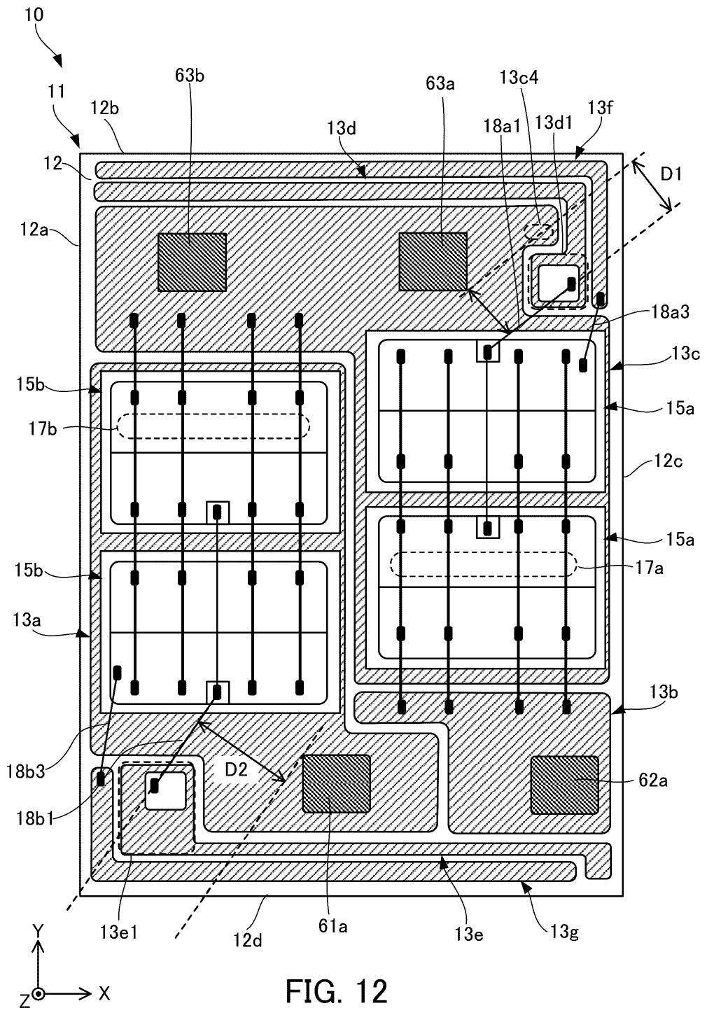

In this third embodiment, a case where the semiconductor chips differ from the chips in the second embodiment will be described with reference to FIG. 12. FIG. 12 is a plan view of a semiconductor unit included in a semiconductor device according to the third embodiment.

The semiconductor unit 10 depicted in FIG. 12 also includes at least the insulated circuit board 11 and the semiconductor chips 15a and 15b. In addition, in the semiconductor unit 10, the main current wires 17a and 17b, the control wires 18a1, 18a2, 18b1, and 18b2, and the sensing wires 18a3 and 18b3 are laid out in the same way as in the semiconductor units 10 in the first and second embodiments. In the present semiconductor unit 10, the positive electrode terminal 61a and the negative electrode terminal 62a of the wiring members 61 and 62 and the two output terminals 63a and 63b of the wiring member 63 are bonded in the same way as in the semiconductor units 10 in the second embodiment.

However, the semiconductor chips 15a and 15b included in the semiconductor units 10 of the present embodiment are reverse conducting (RC)-IGBTs. The withstand voltage of the semiconductor chips 15a and 15b is 1700 V.

The width in the ±X direction of each semiconductor chip 15a is equal to or less than the width in the ±X direction of the chip region 13c1 of the output conductive pattern 13c. The width in the same direction of each semiconductor chip 15b is also equal to or less than the width in the same direction of the chip region 13a1 of the positive electrode conductive pattern 13a. The two semiconductor chips 15a are bonded to the chip region 13c1 of the output conductive pattern 13c via bonding members 19 so as to be aligned in the ±Y direction. Likewise, the two semiconductor chips 15b are bonded to the chip region 13a1 of the positive electrode conductive pattern 13a via bonding members 19 so as to be aligned in the ±Y direction.

The control electrodes 15a1 of the semiconductor chips 15a and the connection region 13d1 of the control conductive pattern 13d are electrically connected by the control wire 18a1. In the present embodiment also, the connection region 13d1 of the control conductive pattern 13d is provided in the recess 13c3 of the output conductive pattern 13c. This means that the connection region 13d1 of the control conductive pattern 13d is separated from the output terminal 63a. Accordingly, the shortest distance D1 between the control wire 18a1, which connects the connection region 13d1 of the control conductive pattern 13d and the control electrode 15a1 of the semiconductor chip 15a, and the output terminal 63a closest to the connection region 13d1 out of the two output terminals 63a and 63b may be made longer than a predetermined distance. As described earlier, the withstand voltage of the semiconductor chips 15a is 1700 V. According to FIG. 11, the terminal-to-wire distance at which discharge occurs at 1700 V is around 2.2 mm. In the case of FIG. 12, the actual shortest distance D1 is around 3.18 mm, which is larger than 2.2 mm. This means that sufficient withstand voltage characteristics are achieved between the connection region 13d1 of the control conductive pattern 13d and the output terminal 63a. The occurrence of partial discharge between the output terminal 63a and the control wire 18a1 is suppressed, which prevents short circuiting between the output terminal 63a and the control wire 18a1. As a result, while improving the ease with which current flows at the output terminals 63a and 63b, the occurrence of failures at the semiconductor chips 15a is suppressed, which suppresses a fall in the reliability of the semiconductor device 1.

Note that a configuration where RC-IGBTs are used for the semiconductor chips 15a and 15b has been described here as an example. However, in place of RC-IGBTs, power metal-oxide-semiconductor field-effect transistors (MOSFETs) with silicon carbide as a main component may be used for the semiconductor chips 15a and 15b. In a power MOSFET, the body diode functions as an FWD. Each of the semiconductor chips 15a and 15b in this case includes a drain electrode as an input electrode on the rear surface, and a gate electrode as a control electrode and a source electrode as an output electrode on the front surface.

### Fourth Embodiment

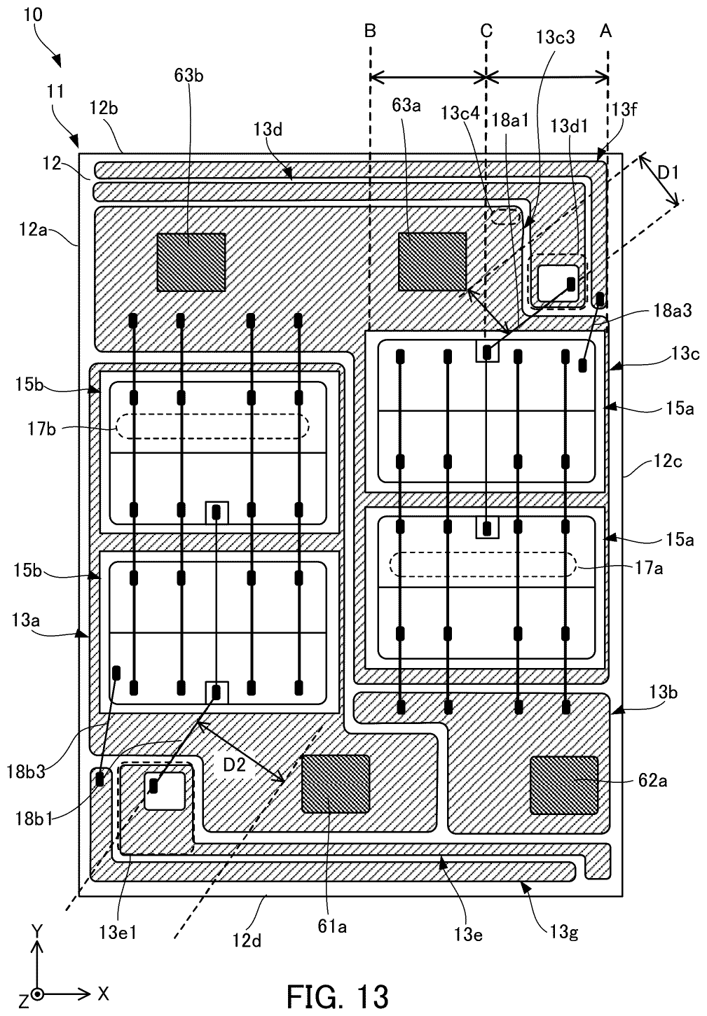

In this fourth embodiment, a configuration where the recess 13c3 of the output conductive pattern 13c differs from the recess in the third embodiment will be described with reference to FIG. 13. FIG. 13 is a plan view of a semiconductor unit included in a semiconductor device according to the fourth embodiment.

Like the semiconductor unit 10 of the third embodiment, the semiconductor unit 10 depicted in FIG. 13 also includes at least the insulated circuit board 11 and the semiconductor chips 15a and 15b. In this semiconductor unit 10 also, the main current wires 17a and 17b, the control wires 18a1 and 18a2, and the sensing wires 18a3 and 18b3 are laid out in the same way as in the semiconductor unit 10 of the third embodiment. In addition, in this semiconductor unit 10, a positive electrode terminal 61a and a negative electrode terminal 62a of the wiring members 61 and 62 and output terminals 63a and 63b of the wiring member 63 are bonded in the same way as in the semiconductor unit 10 in the second embodiment.

However, the shape of the recess 13c3 of the output conductive pattern the 13c included in the semiconductor unit 10 in the present embodiment differs from the shape in the second embodiment. In plan view, the recess 13c3 is recessed on the +X direction side (the first side) of the terminal region 13c2 of the output conductive pattern 13c from the +X direction side toward the −X direction side (the second side). In plan view, a corner portion of the terminal region 13c2 is cut away to form the recess 13c3. The recess 13c3 is L-shaped in plan view and faces the +X direction and the +Y direction. The recess 13c3 in this configuration may also be located in the terminal region 13c2 between the center line C of the chip region 13c1 and the end portion A. It is preferable for the position of the recess 13c3 to be closer to the end portion A and adjacent to the chip region 13c1.

The control conductive pattern 13d is L-shaped corresponding to the shape of the recess 13c3. The connection region 13d1 of the control conductive pattern 13d is disposed in the recess 13c3 of the output conductive pattern 13c. The control conductive pattern 13d extends from the connection region 13d1 to the long side 12a along the outer edge of the terminal region 13c2 of the output conductive pattern 13c in parallel with the long side 12c and the short side 12b.

With this configuration also, the connection region 13d1 of the control conductive pattern 13d is separated from the output terminal 63a that is closer to the connection portion 13d1 out of the two output terminals 63a and 63b. This means that the shortest distance D1 between the output terminal 63a and the control wire 18a1, which connects the control electrode 15a1 of a semiconductor chip 15a and the connection region 13d1 of the control conductive pattern 13d, may be made longer than a predetermined distance. By doing so, sufficient withstand voltage characteristics are achieved between the connection region 13d1 of the control conductive pattern 13d and the output terminal 63a. In addition, the output terminal 63a and the output terminal 63b may be spaced apart. As a result, while improving the ease with which current flows into the output terminals 63a and 63b, the occurrence of failures at the semiconductor chips 15a may be suppressed, which in reliability the of the suppresses a fall semiconductor device 1.

Note that a configuration where RC-IGBTs are used as the semiconductor chips 15a and 15b has been described here as an example. For this configuration also, in the same way as in the first embodiment, the semiconductor chips 16a and 16b which include diode elements may be used together with the semiconductor chips 15a and 15b which include switching elements.

The disclosed techniques make it possible to achieve sufficient withstand voltage characteristics and thus suppress a fall in reliability.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
an output conductive pattern, including:
a first part, which is of a shape of a rectangle having first, second, third, and fourth sides, the first and second sides extending in a first direction, and the third and fourth sides extending in a second direction perpendicular to the first direction, and
a second part, having a first side and a second side extending in the first direction, and a third side extending in the second direction, the third side of the second part being joined to the third side of the first part;
a first semiconductor chip disposed in the first part of the output conductive pattern, the first semiconductor chip including a control electrode provided on a front surface thereof and at the third side of the first part;
an output terminal disposed in the second part of the output conductive pattern; and
a control conductive pattern including a connection part that is electrically connected to the control electrode, the control conductive pattern being adjacent to the second part of the output conductive pattern on an opposite side of the output conductive pattern to the first part in a plan view of the semiconductor device, wherein
the second part of the output conductive pattern has a recess on the first side that is adjacent to the first part and is recessed from the first side toward the second side thereof, and
the connection part of the control conductive pattern is provided in the recess.

2. The semiconductor device according to claim 1, wherein the output terminal is disposed in a center portion of the second part of the output conductive pattern in the second direction.

3. The semiconductor device according to claim 1, wherein
the output terminal is provided in a number of at least two, and
the at least two output terminals are disposed in a row in the second direction in the second part of the output conductive pattern.

4. The semiconductor device according to claim 3, wherein the control electrode is provided at a center of the first semiconductor chip with respect to the second direction.

5. The semiconductor device according to claim 4, wherein
in the second direction, a width of the first semiconductor chip is equal to or less than half a width of the first part of the output conductive pattern, and
two first semiconductor chips are disposed side by side in the second direction in the first part of the output conductive pattern.

6. The semiconductor device according to claim 5, wherein
each of the first semiconductor chips further includes an output electrode provided on the front surface thereof,
the semiconductor device further comprises a second semiconductor chip which includes a diode element and is disposed in the first part of the output conductive pattern so as to be adjacent to the first semiconductor chips on an opposite side to the second part of the output conductive pattern, and
the second semiconductor chip is electrically connected to the output electrodes of the first semiconductor chips and the first part of the output conductive pattern.

7. The semiconductor device according to claim 5, further comprising a wire connecting the connection part of the control conductive pattern and the control electrode of each of the first semiconductor chips,
wherein a shortest distance from the wire to one of the at least two output terminals that is closest to the connection part in the plan view is 1.5 mm or more.

8. The semiconductor device according to claim 5, wherein a withstand voltage of the first semiconductor chips is 1200 V.

9. The semiconductor device according to claim 5, wherein each first semiconductor chip is an insulated gate bipolar transistor.

10. The semiconductor device according to claim 5, further comprising a wire connecting the connection part of the control conductive pattern and the control electrode of each of the first semiconductor chips,
wherein a shortest distance from the wire to one of the at least two output terminals that is closest to the connection part in the plan view is 2.2 mm or more.

11. The semiconductor device according to claim 5, wherein a withstand voltage of the first semiconductor chips is 1700 V.

12. The semiconductor device according to claim 5, wherein each first semiconductor chip is a reverse conducting insulated gate bipolar transistor.

13. The semiconductor device according to claim 4, wherein in the second direction, a width of the first semiconductor chip is equal to or smaller than a width of the first part of the output conductive pattern.

14. The semiconductor device according to claim 1, wherein the control electrode is provided closer to the first side or the second side than a center of the front surface in the second direction.

15. The semiconductor device according to claim 1,
wherein the second part of the output conductive pattern includes a linking region electrically connected to another output conductive pattern on an outside.

16. The semiconductor device according to claim 15, wherein the recess included in the second part of the output conductive pattern is U-shaped with an opening facing the first side in the plan view.

17. The semiconductor device according to claim 16, wherein the linking region is included along the recess.

18. The semiconductor device according to claim 15, wherein the recess included in the second part of the output conductive pattern is L-shaped with an opening facing the first side and the first direction in the plan view.

19. The semiconductor device according to claim 1, wherein the recess included in the second part of the output conductive pattern is provided closer to the first side than a center of the first part of the output conductive pattern in the second direction.
